(19) United States
(12) Patent Application Publication
(10) Pub. No.: US 2005/0126627 A1
(43) Pub. Date: Jun. 16, 2005

(54) Solar cell and method for producing the same

(75) Inventor: Shigeki Hayashida, Kitakatsuragi-gun (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/989,486

(22) Filed: Nov. 17, 2004

(30) Foreign Application Priority Data
Nov. 19, 2003 (JP) 2003-389490

(51) Int. Cl. H01L 31/00

(52) U.S. Cl. 136/257; 136/259

(57) ABSTRACT

A solar cell includes at least: a semiconductor substrate having a pn junction and a plurality of microscopic depressions formed in a light-receiving surface thereof; a front electrode formed on the light-receiving surface of the substrate; and a rear electrode formed on a rear surface of the substrate. The plurality of depressions each have a ratio of the maximum depth to the maximum diameter of 0.5 to 2.

### CROSS-REFERENCE TO RELATED APPLICATION

This application is related to Japanese Patent Application No. 2003-389490 filed on Nov. 19, 2003, whose priority is claimed under 35 USC §119, the disclosure of which is incorporated by reference in its entirety.

### BACKGROUND OF THE INVENTION

1. Field of the Invention

The present invention relates to a solar cell and a method for producing the same, and more particularly, to a method of forming irregularities on a surface of a silicon semiconductor substrate for reducing reflection of light incident on the surface.

2. Description of Related Art

In order to improve photoelectric conversion efficiency, conventional solar cells have been constructed to have a plurality of irregularities on a surface of a semiconductor substrate. This allows light reflected at the surface of the substrate to be incident on the surface again, so that reflection losses can be reduced. Where the solar cells are formed using a (100)-oriented single-crystal silicon substrate, a plurality of pyramid-like projections are usually formed on the substrate surface by immersing the substrate, for about 30 minutes to 1 hour, into a 1%-5% sodium hydroxide solution, containing isopropyl alcohol, which is maintained at 70° C. to 90° C. This method utilizes the difference in etch rate between the (100) plane and (111) plane.

However, where the substrate is of polycrystalline silicon, this method can not significantly reduce the surface reflectivity thereof because polycrystalline silicon has various plane directions.

Under such circumstances, there has been proposed in Japanese Unexamined Patent Publication No. 2000-101111 a production method for producing a solar cell on which a plurality of microscopic irregularities are formed by etching. In this method, a polycrystalline silicon substrate is etched in a chlorine trifluoride gas (ClF₃) atmosphere for 15 minutes, for example, to form the plurality of microscopic irregularities of smaller than 1 μm on a surface of the silicon substrate.

The reflectivity of thus formed substrate is reduced as low as about 10%. The irregularities formed on the substrate, however, have pointed tips and thus, a pn junction provided under a light-receiving surface of the substrate may be destroyed at heating of a metal paste for the formation of electrodes. To avoid this, the silicon substrate surface on which the irregularities are formed is etched again with, for example, a 10% sodium hydroxide aqueous solution for about 5 minutes.

In other words, the etching using chlorine trifluoride gas is performed to reduce the reflectivity of the substrate to about 10%, and then the alkaline etching is performed to smooth out the edges of the irregularities sharpened by the previous etching. This allows the projections of the irregularities to have rounded tips. Further, the short-circuit current (Jsc), the open-circuit voltage (Voc), and the fill factor (FF) of the solar cell are increased.

The gas etching using ClF₃, as described above, may greatly reduce the reflectivity of the substrate surface. However, as a result of a detailed examination of the gas-etched surface of the substrate by SEM (Scanning Electron Microscope), it is found that a number of small pores are formed in the surface, i.e., the surface is porous as shown in the SEM photograph of FIG. 17(a), owing to the irregularities being too microscopic. It is also found from FIG. 17(b) that considerably deep irregularities are formed after the gas etching.

The surface of the same substrate after being etched with an alkaline etching solution containing about 5% of, for example, NaOH or K(OH is also carefully examined. It is found, as shown in FIG. 18(a), that the porous state of the surface still remains while the surface is smoothed, and as can be seen from FIG. 18(b), the considerably deep irregularities still remain on the surface.

If a prototype cell is made with a substrate in such condition, recombination of generated carriers occurs in the surface of the substrate, and thereby the short-circuit current and the open-circuit voltage decrease. If alkaline etching conditions are changed for removing the pores formed in the substrate surface, the low-reflectivity of the substrate surface can not be maintained.

FIG. 19, FIG. 20 and FIG. 21 show SEM photographs of the surfaces of the silicon substrates after being etched with an alkaline etching solution of 5% KOH for 180 seconds, 240 seconds and 300 seconds, respectively. FIG. 22 shows the reflectivity of each substrate thus etched. Seen from FIG. 19, FIG. 20 and FIG. 21, as the etch time increases, more pores are removed, that is, the substrate surface becomes as smooth as it was before the gas etching was performed. As shown in FIG. 22, it is also found that the reflectivity goes higher as the etch time increases. From these facts, it is understood that maintaining the low-reflectivity of the substrate surface and removing the pores formed in the substrate surface are two contradictory objects to be achieved, and thus, realization of these two objects in one device is extremely difficult. In other words, particular consideration needs to be given to the surface configuration of the substrate in order to reduce the reflectivity while eliminating the pores formed in the substrate surface.

### SUMMARY OF THE INVENTION

In view of the foregoing, it is an object of the present invention to provide a solar cell having fine solar cell properties and a reduced surface reflection of a semiconductor substrate, and to provide a production method therefor.

In accordance with the present invention, provided is a solar cell comprising at least: a semiconductor substrate having a pn junction and a plurality of microscopic depressions formed in a light-receiving surface thereof; a front electrode formed on the light-receiving surface of the substrate; and a rear electrode formed on a rear surface of the substrate, wherein the plurality of depressions each have a ratio of the maximum depth to the maximum diameter of 0.5 to 2.

Further, there is also provided a method for producing a solar cell, comprising the steps of: (a) forming a plurality of microscopic depressions in at least a light-receiving surface of a first-conductivity type semiconductor substrate; (b) diffusing second-conductivity type impurities into the light-receiving surface having the microscopic depressions of the semiconductor substrate to form a pn junction in the substrate; and (c) forming a front electrode and a rear electrode on the light-receiving surface and a rear surface of the semiconductor substrate, respectively, wherein in the step (a), each of the plurality of microscopic depressions is formed to have a ratio of the maximum depth to the maximum diameter of 0.5 to 2.

### BRIEF DESCRIPTION OF THE DRAWINGS

FIG. 1 is a schematic sectional view of a polycrystalline silicon substrate of the present invention;

FIG. 2 is a schematic sectional view of a solar cell of the present invention that is made using the polycrystalline silicon substrate of FIG. 1;

FIG. 3(a) and FIG. 3(b) are a top SEM image and a 60-degree oblique SEM image, respectively, of a surface of a polycrystalline silicon substrate according to Embodiment 1 of the present invention;

FIG. 4(a) and FIG. 4(b) are a top SEM image and a 60-degree oblique SEM image, respectively, of a surface of a polycrystalline silicon substrate according to Embodiment 2 of the present invention;

FIG. 5(a) and FIG. 5(b) are a top SEM image and a 60-degree oblique SEM image, respectively, of a surface of a polycrystalline silicon substrate according to Embodiment 3 of the present invention;

FIG. 6 is a graph showing the surface reflectivity of the polycrystalline silicon substrates according to Embodiments 1 to 3 of the present invention and that of a polycrystalline silicon substrate according to a comparative example;

FIG. 7 is a graph showing the reflectivity of solar cells according to Embodiments 1a and 1b of the present invention and that of a solar cell according to the comparative example;

FIG. 8 is a schematic sectional view of a polycrystalline silicon substrate, for explaining a process step of the solar cell of the present invention;

FIG. 9 is a schematic sectional view of the polycrystalline silicon substrate in which uniform irregularities (a uniform texture) are formed on surfaces of the substrate in a process step of the present invention;

FIG. 10 is a schematic sectional view of the polycrystalline silicon substrate in which the surface thereof is smoothed in a process step of the present invention;

FIG. 11 is a schematic sectional view of the polycrystalline silicon substrate in which an n+ diffusion region is formed in a light-receiving surface side thereof in a process step of the present invention;

FIG. 12 is a schematic sectional view of the polycrystalline silicon substrate in which an anti-reflection film is formed on the light-receiving surface having the microscopic depressions thereof in a process step of the present invention;

FIG. 13 is a schematic sectional view of the polycrystalline silicon substrate in which a p+ region is formed in a rear surface side thereof in a process step of the present invention;

FIG. 14 is a schematic sectional view of the polycrystalline silicon substrate in which front and rear silver electrodes are formed on the substrate in a process step of the present invention;

FIG. 15 is a schematic sectional view of the polycrystalline silicon substrate (completed solar cell) in which the front and rear silver electrodes are covered with solder in a process step of the present invention;

FIG. 16 is a diagram showing the etch depth dependence on the etch time in wet etching of the polycrystalline silicon substrate of the present invention, when acid etching solutions containing a 60% nitric acid aqueous solution, a 49% hydrofluoric acid aqueous solution and pure water in different volume ratios are used;

FIG. 17(a) and FIG. 17(b) are a top SEM image and a 60-degree oblique SEM image, respectively, of a surface of a conventional polycrystalline silicon substrate after being subjected to gas etching;

FIG. 18(a) and FIG. 18(b) are a top SEM image and a 60-degree oblique SEM image, respectively, of the surface of the conventional polycrystalline silicon substrate after being subjected to gas etching and then alkaline etching:

FIG. 19 is a top SEM image of a surface of a conventional polycrystalline silicon substrate after being subjected to gas etching and then alkaline etching with 5% KOH for 180 seconds;

FIG. 20 is a top SEM image of a surface of a conventional polycrystalline silicon substrate after being subjected to gas etching and then alkaline etching with 5% KOH for 240 seconds;

FIG. 21 is a top SEM image of a surface of a conventional polycrystalline silicon substrate after being subjected to gas etching and then alkaline etching with 5% KOH for 300 seconds; and

FIG. 22 is a graph showing the light reflectivity of the surface of each polycrystalline silicon substrate shown in FIG. 19 to FIG. 21.

### DESCRIPTION OF THE PREFERRED EMBODIMENTS

According to the present invention, a solar cell having a plurality of microscopic depressions formed in a light-receiving surface of a semiconductor substrate is provided. Since each depression has a maximum depth/maximum diameter ratio of 0.5 to 2, the solar cell of the present invention can have excellent properties (such as photoelectric conversion efficiency, short-circuit current, open-circuit voltage, fill factor and maximum power) and can greatly reduce the reflectivity of light incident on the light-receiving surface of the substrate.

In the present invention, the semiconductor substrate may be any that is used in the art. Examples of the substrate include crystalline substrates such as of single-crystal silicon, polycrystalline silicon and microcrystalline silicon, amorphous substrates such as of amorphous silicon (a-Si) and a-Sic, and compound semiconductor substrates such as of GaAs and InP.

Though it has been hitherto difficult to form low-reflective depressions in the semiconductor substrates and maintain excellent solar cell properties at the same time, the polycrystalline silicon substrates and single-crystal substrates having crystal orientation (111) may be suitably used as a semiconductor substrate of the present invention.

The semiconductor substrate used in the solar cell of the present invention has a plurality of depressions in at least the light-receiving surface thereof. The plurality of depressions each have a ratio of the maximum depth to the maximum diameter (maximum depth/maximum diameter ratio) of 0.5 to 2, and more preferably 1.

Where the maximum depth/maximum diameter ratio of each depression is less than 0.5, the reflectivity of the depressions increases. This makes the photoelectric conversion efficiency of the solar cell to be reduced, rendering the cell impractical. Where the maximum depth/maximum diameter ratio of each depression is more than 2, the reflectivity of the depressions decreases, but recombination of generated carriers occur in the surface of the substrate. This makes the solar cell properties such as short-circuit current and open-circuit voltage to be reduced.

Where the maximum depth/maximum diameter ratio of each depression is 0.5 to 2, the diameter of each depression is preferably not greater than 2 μm and the depth of each depression is preferably not greater than 4 μm. Where the diameter of each depression is greater than 2 μm, the reflectivity thereof tends to increase.

The plurality of depressions herein mean those formed by etching the surface of the semiconductor substrate. The plurality of depressions may slightly vary in configuration and size, and may be densely and independently formed in continuous manner. Further, adjacent depressions may overlap one another.

Owing to the plurality of depressions having nonuniform configurations and sizes, the cross-sectional profile of the light-receiving surface of the substrate has a plurality of ups and downs so complex as the ridge of sharp mountains.

The “diameter” of each depression herein includes the diameter of a depression that is almost circular in plan view, but not necessarily perfectly circular. The “depth” of each depression herein means a dimension from the open end to the deepest point of each depression.

The plurality of depressions formed in the light-receiving surface of the semiconductor substrate may all have a maximum depth/maximum diameter ratio of 0.5 to 2. Alternatively, only the depressions in a predetermined area of the light-receiving surface (for example, the center area or several areas near the center and the periphery of the light-receiving surface, each area having a size of 15 μm×13 μm) may have a maximum depth/maximum diameter ratio of 0.5 to 2. In other words, the light-receiving surface of the substrate may include areas where the maximum depth/maximum diameter ratio of a depression falls outside the range of 0.5 to 2. For example, there may be, in an area of 15 μm×13 μm, about one to thirty depressions whose maximum depth/maximum diameter ratio falls outside the range of 0.5 to 2.

The semiconductor substrate of the present invention has a pn junction therein. This means that an impurity diffusion region of second conductivity type is formed in the front surface side (light-receiving surface side) of the semiconductor substrate of first conductivity type. Where the first conductivity type is n-type, the second conductivity type is p-type, and where the first conductivity type is p-type, the second conductivity type is n-type. Examples of p-type impurities include boron and aluminum, and examples of n-type impurities include phosphorus and arsenic. Where the substrate is of silicon, it preferably has a specific resistance of about 0.1 Ω·cm to 10 Ω·cm irrespective of its conductivity type.

The solar cell of the present invention includes, as described above, the semiconductor substrate having the pn junction and the plurality of microscopic depressions formed in the light-receiving surface thereof; the front electrode formed on the light-receiving surface of the substrate; and a rear electrode formed on a rear surface of the substrate. In addition to the above, the solar cell may include an anti-reflection film on the light-receiving surface of the substrate.

As the anti-reflection film, a single-layered or multilayered film of insulating films such as a silicon nitride film and a silicon oxide film may be used. The thickness of the anti-reflection film is set such that the light reflection at the interface of the anti-reflection film and the semiconductor substrate is reduced.

For example, where the refractive index of the anti-reflection film is about 1.9 to 2.1, the thickness of the anti-reflection film is preferably 50 nm to 80 nm, and more preferably 50 nm to 60 nm. Where the thickness of the anti-reflection film is less than 50 nm, its reflectivity for visible light at relatively short wavelengths (400 nm to 500 nm) suddenly increases. Where the thickness of the anti-reflection film is more than 80 nm, its reflectivity becomes the lowest for light at long wavelengths of not shorter than 600 nm, and its reflectivity increases at short wavelengths of shorter than 600 nm.

The semiconductor substrate having the plurality of microscopic depressions used in the solar cell of the present invention may be made according to the production method described below.

According to the production method of the present invention, a semiconductor substrate of a thickness of 100 μm to 500 μm, for example, is cut from a semiconductor ingot, and surfaces of the substrate are washed to remove damages caused by the slicing. In at least one of the front and rear surfaces (one that is to serve as the light-receiving surface) of the substrate, the plurality of microscopic depressions are formed. The surfaces of the substrate may be washed by means of etching with, for example, an alkaline solution (such as NaOH or KOOH) or mixed acid (of hydrofluoric acid and nitric acid), and rinsing with pure water.

According to the production method of the present invention, the plurality of depressions each having a maximum depth/maximum diameter ratio of 0.5 to 2 may be formed at least in the light-receiving surface of the semiconductor substrate by the steps of: (a1) forming the plurality of depressions in the light-receiving surface of the substrate by means of dry etching; and (a2) smoothing the light-receiving surface of the substrate having the plurality of depressions by means of wet etching at an etch rate of not higher than 2 μm/min with an etching solution containing a mixture of at least nitric acid, hydrofluoric acid and water.

The etching gas used in the dry etching of the step (a1) is not particularly limited as long as the semiconductor substrate can be etched, and may be, for example, Cl, ClF₃, SF₆ or the like. As diluting gas used in the dry etching, Ar, N₂ or the like may be used. The etching conditions may be, for example, as follows. Flow rate of etching gas (e.g. ClF₃): 0.05 L/min to 0.5 L/min; flow rate of diluting gas (e.g. Ar): 1 L/min to 5 L/min; pressure: 1 Torr to 700 Torr; and etch time: 1 min to 30 min.

The etching solution used in the wet etching of the step (a2) is preferably a mixed solution of at least nitric acid, hydrofluoric acid and water as described above. To make the etch rate not higher than 2 μm/min, particularly preferable is a mixed solution of not less than 140 parts by volume to not more than 240 parts by volume of water and 100 parts by volume of mixed acid of nitric acid and hydrofluoric acid.

More specifically, where mixed acid of a 60% nitric acid aqueous solution and a 49% hydrofluoric acid aqueous solution is used, for example, the volume ratio of the aqueous nitric acid solution and the aqueous hydrofluoric acid solution in the mixed acid is preferably 10:1 to 20:1, and more preferably 20:1. Further, the volume ratios of the 60% nitric acid aqueous solution, the 49% hydrofluoric acid aqueous solution and water in the etching solution is preferably 20:1:9 to 20:1:21, and more preferably, 20: 1:9 to 20:1:14.

Where the amount of water is less than 140 parts by volume relative to 100 parts by volume of the mixed acid, the etch rate increases to higher than 2 μm/min, which is too fast for forming the depressions each having a depth of about 1 μm to 2 μm. This makes it difficult to form depressions of desirable configuration and size with fine control. Where the amount of water is more than 240 parts by volume relative to 100 parts by volume of the mixed acid, the etch rate decreases. The slow etch rate makes it easier to control the configuration and size of the depressions, but on the other hand, reduces the production efficiency.

The etching solution may be a mixed solution containing a proper amount of acetic acid and a mixture of nitric acid and hydrofluoric acid.

According to conventional methods for producing solar cells, gas etching of a semiconductor substrate causes severe damage to the substrate, whereby the solar cell properties are degraded. Even when wet etching with an alkaline solution is conducted after the gas etching, it is not possible to achieve excellent solar cell properties and maintain low reflectivity of a light-receiving surface of the substrate at the same time.

According to the solar cell production method of the present invention, such problems can be resolved, and a solar cell having excellent properties can be made. In other words, wet etching using the aforementioned etching solution is conducted after the gas etching so that the plurality of depressions (excellent textured surface) each having a maximum depth/maximum diameter ratio of 0.5 to 2 can be easily formed in the light-receiving surface of the substrate.

It has been hitherto impossible to form a plurality of depressions (excellent textured surface) in the polycrystalline silicon substrates and the single-crystal silicon substrates having crystal orientation (111) by conventional alkaline etching. According to the solar cell production method of the present invention, however, it is possible to make the light-receiving surface of the substrate to be uniformly low-reflective, allowing an excellent solar cell to be achieved.

In the solar cell production method of the present invention, the pn junction is formed in the substrate by any known technique such as solid-phase diffusion, vapor-phase diffusion or ion-implantation. For example, where an n+ diffusion region is to be formed in the surface of a p-type semiconductor substrate, a diffusion source layer composed of PSG (P₂O₅, SiO₂), ASG(As, SiO₂) or the like is formed on the surface of the substrate, and the layer is heated to form the n+ diffusion region. The conditions of the heating are preferably optimized for setting the junction depth at such a depth that the incident light can be converted into the greatest amount of current.

The anti-reflection film may be formed by any known technique such as a CVD method, a sputtering method, a vacuum-deposition method or the like. The front and rear electrodes may be formed by applying a metal paste (silver, for example) by means of a known technique such as a printing method, and then heating the paste.

With reference to the attached drawings, the present invention will hereinafter be described in detail by way of embodiments thereof. It should be understood that the invention be not limited to these embodiments.

### EMBODIMENTS

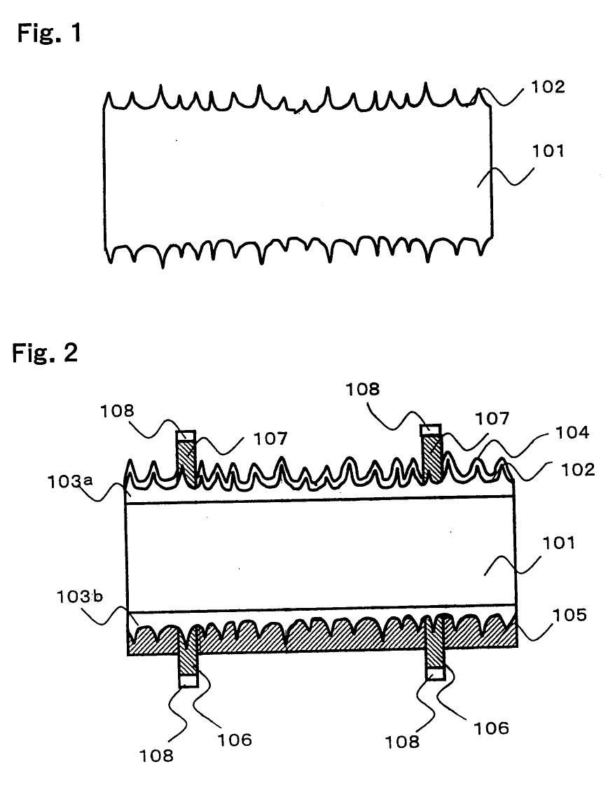

FIG. 1 is a schematic sectional view of a silicon substrate of the present invention. FIG. 2 is a schematic sectional view of a solar cell of the present invention that is made using the silicon substrate of FIG. 1.

The solar cell according to the present invention includes a polycrystalline silicon substrate 101 having various crystal orientations and a plurality of microscopic depressions 102 formed in surfaces thereof, an anti-reflection film 104 formed on an entire light-receiving surface of the substrate 101, an Al electrode 105 formed on nearly an entire rear surface of the substrate 101, silver electrodes 106, 107 formed partially on the rear surface and the light-receiving surface of the substrate 101, respectively, and solder 108 for covering the silver electrodes 106, 107.

The polycrystalline silicon substrate 101 has a thickness of about 200 μm to 400 μm (in the embodiments, 300 μm) and contains p-type impurities of about 1E15 cm⁻³ to 1E16 cm⁻³. The substrate includes an n+ region 103a (thickness: about 0.1 μm to 0.5 μm, impurity concentration: about 1E18 cm⁻³ to 1E19 cm⁻³) in the light-receiving surface side thereof and a p+ region 103b (thickness: about 0.2 μm to 1 μm, impurity concentration: about 1E18 cm⁻³ to 1E19 cm⁻³) in the rear surface side thereof.

The anti-reflection film 104 is composed of a silicon nitride film (SiN), and has a thickness of 60 nm when the refractive index thereof is around 2.1. The thickness of the anti-reflection film needs to be determined so that the reflectivity is minimized in view of the refractive index of a film to be used.

Such solar cells as described above are formed as Embodiments 1-3 using polycrystalline silicon substrates having depressions of three different types of configurations and sizes. Also, as a comparative example, a solar cell is formed using a polycrystalline silicon substrate in which no depression is formed and the damage caused by slicing is removed.

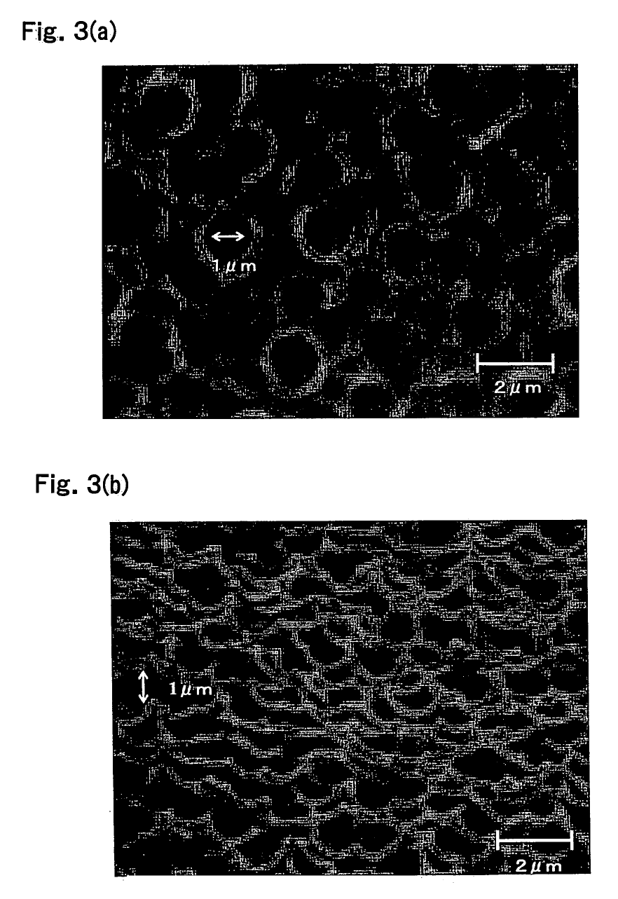

FIG. 3(a) and FIG. 3(b) are a top SEM image and a 60-degree oblique SEM image, respectively, of a plurality of depressions having a first type of configuration and size formed in surfaces of the substrate of Embodiment 1.

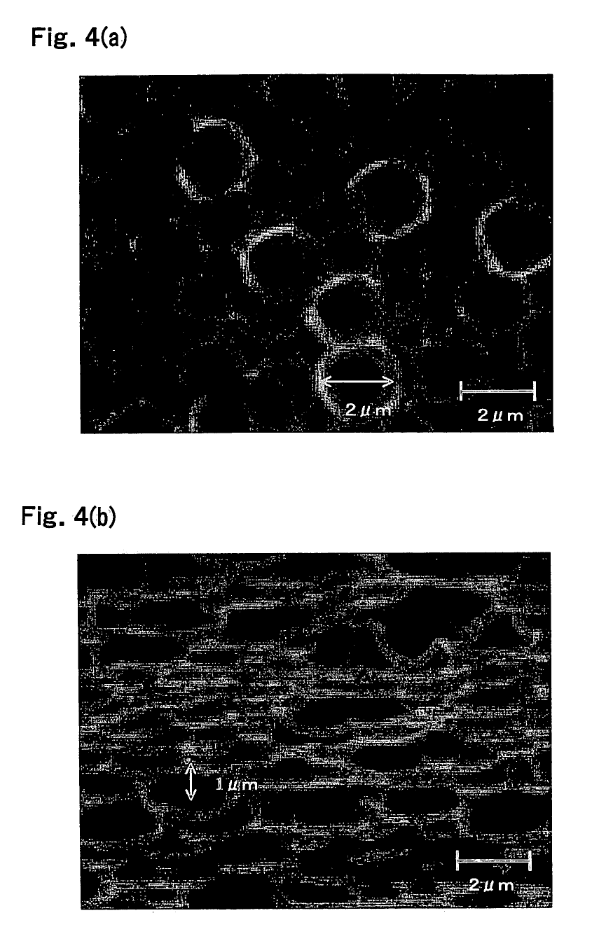

FIG. 4(a) and FIG. 4(b) are a top SEM image and a 60-degree oblique SEM image, respectively, of a plurality of depressions a second type of configuration and size formed in surfaces of the substrate of Embodiment 2.

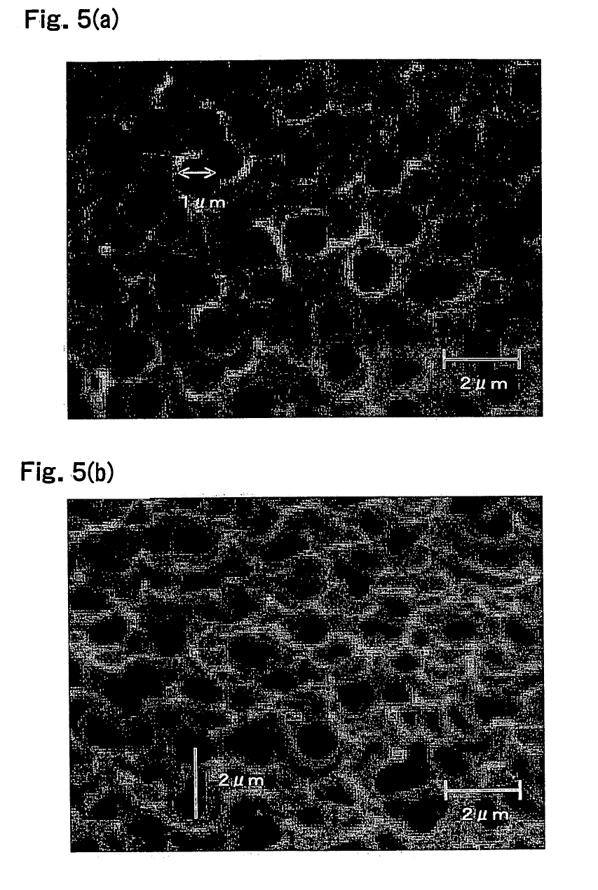

FIG. 5(a) and FIG. 5(b) are a top SEM image and a 60-degree oblique SEM image, respectively, of a plurality of depressions having a third type of configuration and size formed in surfaces of the substrate of Embodiment 3.

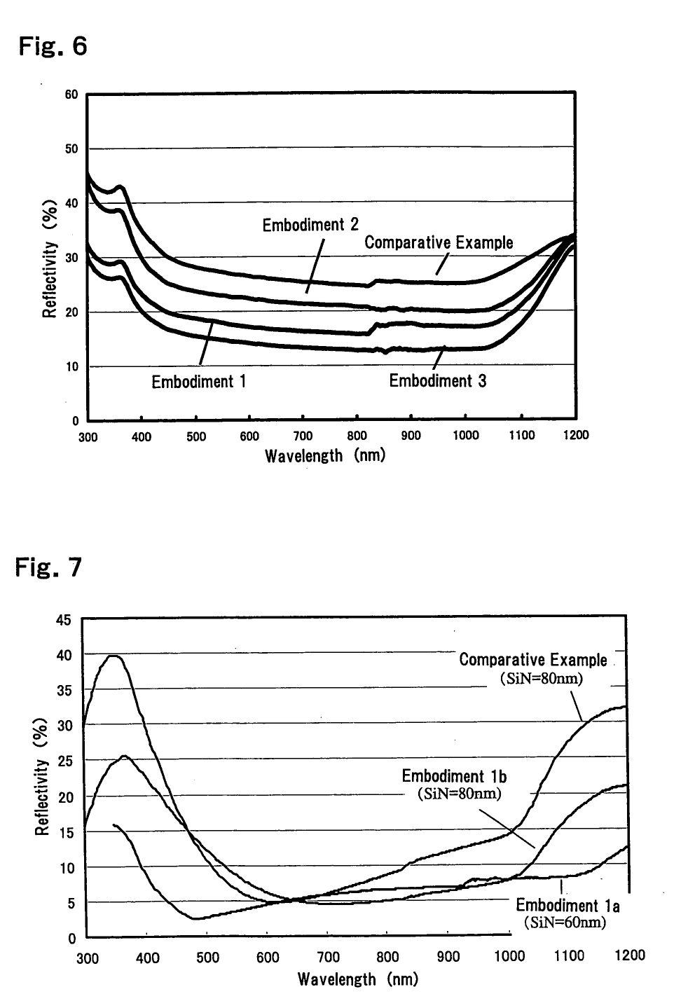

FIG. 6 is a graph showing the surface reflectivity of the polycrystalline silicon substrates according to Embodiments 1 to 3 and the comparative example.

Shown in Table 1 are IV characteristics of the solar cells according to Embodiments 1-3 and the comparative example. In Table 1, Jsc indicates short-circuit current, Voc indicates open-circuit voltage and FF indicates fill factor and Pmax indicates maximum power.

TABLE 1

| | Jsc (mA/cm²) | Voc (V) | FF | Pmax (W) |
|---|---|---|---|---|
| Embodiment 1 | 30.6 | 0.595 | 0.778 | 2.19 |
| Embodiment 2 | 29.9 | 0.594 | 0.761 | 2.11 |
| Embodiment 3 | 29.7 | 0.591 | 0.769 | 2.11 |
| Comparative Example | 29.9 | 0.595 | 0.738 | 2.06 |

According to Table 1, the solar cell of Embodiment 1 is higher in all of the parameters except open-circuit voltage when compared to that of the comparative example. Further, the cell of Embodiment 1 is not lower in open-circuit voltage than that of the comparative example.

Compared to the cell of the comparative example, those of Embodiments 2 and 3 are almost equal or slightly lower in density of the short-circuit current. However, the cells of Embodiments 2 and 3 are greatly improved in fill factor over that of the comparative example, and this makes the cells of the two embodiments to have an improved photoelectric conversion efficiency.

As shown in FIG. 6, light-receiving surfaces of the cells according to Embodiments 1 to 3 have a reduced reflectivity than that of the cell of the comparative example. Particularly, the substrate surface of the cell of Embodiment 3 has the lowest reflectivity. The cell of Embodiment 2 is little lower in reflectivity than that of the comparative example, but there is no remarkable difference in short-circuit current between the cells of Embodiment 2 and the comparative example since the substrate surface of the cell of Embodiment 2 is slightly flatter.

In the solar cell of Embodiment 3, it appears that currents are not sufficiently taken out from the substrate because pores that appear in the substrate after gas etching with ClF₃ are not sufficiently removed. In the cell of Embodiment 3, however, the configuration and size of the depressions are made uniform, allowing a stable fill factor to be obtained. Assumably, this leads to an improvement in photoelectric conversion efficiency of the solar cell.

From the above, it is understood that a solar cell having depressions of configuration and size in between those of the second and third types, that is, the solar cell of Embodiment 1 (having depressions of first type of configuration and size) is effective for achieving a higher photoelectric conversion efficiency.

To determine the effective size range of the depressions formed in the substrate surfaces of the inventive solar cells, the scales of the largest depression and the deepest depression in each of the substrates of Embodiments 1 to 3 are shown in the SEM photographs (of a region of 15 μm×13 μm) of FIG. 3 to FIG. 5, respectively.

In FIG. 3 which shows the substrate surface of the cell of Embodiment 1 whose properties are improved the most, both the maximum diameter and the maximum depth of the depressions are about 1 μm, giving a maximum depth/maximum diameter ratio of 1.

In FIG. 4 which shows the substrate surface of the cell of Embodiment 2, the maximum diameter of the depressions is about 2 μm while the maximum depth is about 1 μm, giving a maximum depth/maximum diameter ratio of 0.5. In FIG. 5 which shows the substrate surface of the cell of Embodiment 3, the maximum diameter of the depressions is about 1 μm while the maximum depth is about 2 μm, giving a maximum depth/maximum diameter ratio of 2.

To achieve a solar cell with excellent properties, it is thus found that the depressions preferably have such a size that at least the maximum diameter of each depression is not greater than 2 μm, and more preferably, such a size that the maximum depth/maximum diameter ratio of each depression is between 0.5 to 2 inclusive. To achieve a solar cell with more effective properties, it is particularly preferable that the depressions have such a size that the maximum depth/maximum diameter ratio of each depression is about 1.

Hence, the formation of the plurality of depressions each having a maximum diameter of not greater than 2 μm and a maximum depth/maximum diameter ratio of 0.5 to 2 (more preferably about 1) in the light-receiving surface of the solar cell allows for an improvement in cell properties.

To make the solar cell properties even more effective, a consideration needs to be given to the thickness of the anti-reflection film 102 (see FIG. 2). An explanation will be hereinafter given on the anti-reflection film.

To make solar cells of Embodiments 1a and 1b, silicon nitride films having a refractive index of about 2.1 and a thickness of 60 nm and 80 nm are formed as the anti-reflection films on the silicon substrates of Embodiment 1, respectively. Also, a silicon nitride film having a refractive index of about 2.1 and a thickness of 80 nm is formed on the substrate of the comparative example (having no depressions) to make a comparative solar cell. The reflectivity of each solar cell thus fabricated is measured at room temperature. The results are shown in FIG. 7.

As shown in FIG. 7, the solar cell of Embodiment 1b is higher in reflectivity than that of the comparative example at wavelengths of about 450 nm to 650 nm. Since these wavelengths have the strongest spectrum intensity, loss of light by reflection occurs and thus, the properties of the solar cell are impaired. Such a problem can be solved by making the thickness of the silicon nitride film provided on the silicon substrate as thin as about 50 nm to 60 nm. By doing so, the solar cell of Embodiment 1b can be lower in reflectivity than that of the comparative example at all wavelengths as in the case of Example la. Accordingly, the cell of Embodiment 1b can have more effective cell properties.

The present invention is not limited to the above embodiments. The values specified in the embodiments are merely an example, and various modifications can be made. Although FIG. 1 illustrates the substrate having the plurality of depressions in both surfaces thereof, a plurality of depressions may be formed only in the light-receiving surface of the substrate.

The configuration of the plurality of depressions is not limited to those shown in the SEM photographs of Embodiments 1 to 3, and it may be almost rectangle as long as reflection of light can be reduced. In such a case, instead of determining the maximum depth/maximum diameter ratio of each depression, the ratio of maximum depth to maximum diagonal length or maximum longer length of each of the almost rectangle depressions (0.5 to 2) can be determined, for example, from the diagonal length or longer length of the almost rectangle.

In the embodiments of the present invention, the p-type silicon substrate having the n+ region formed therein is used, but an n-type silicon substrate having a p+ region formed in a light-receiving surface side thereof may be used and, if necessary, an n+ region may be additionally formed in a rear surface side thereof. Though the polycrystalline silicon substrate is used in the embodiments, a single-crystal silicon substrate of crystal orientation (111), on which irregularities can not be easily formed by alkaline etching, may be used.

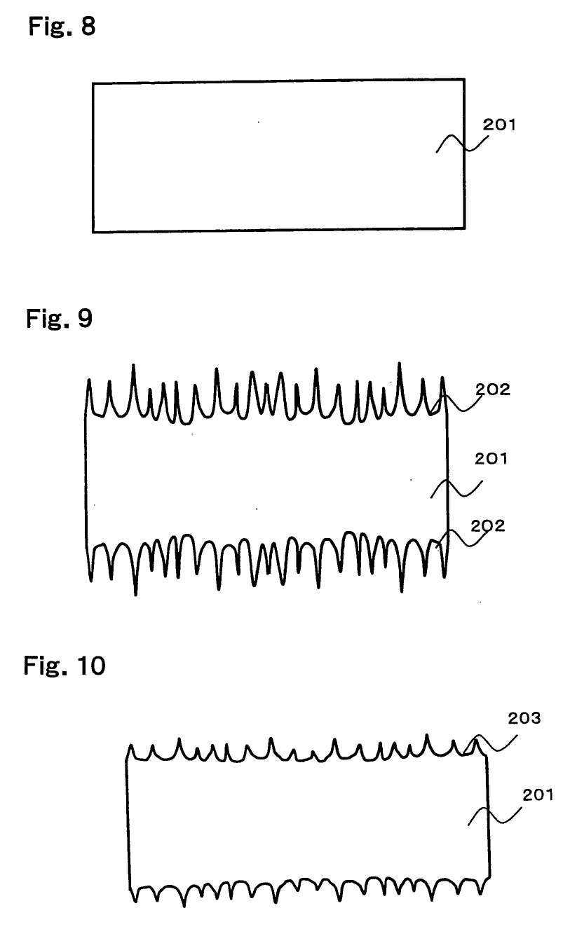

Referring to FIG. 8 to FIG. 15, a method of producing the solar cell of the present invention having the above structures will now be described.

A sliced polycrystalline silicon substrate 201 shown in FIG. 8 is immersed into, for example, a NaOH or KOH solution at 80° C. to 100° C. for about 10 to 30 minutes to remove the damage formed on its surface by slicing, if necessary.

Then, for forming uniform irregularities on surfaces of the substrate 201 as shown in FIG. 9, the substrate 201 is set on a quartz boat and then inserted into a pressure-reducible quartz or stainless steel tube furnace. After the pressure inside the furnace is reduced, the temperature of the substrate 201 is kept at 25° C.

Subsequently, ClF₃ gas as etching gas and Ar as diluting gas are introduced into the furnace. Etching of the substrate is carried out for 10 to 15 minutes at a ClF₃ flow rate of 0.2 L/min and an Ar flow rate of 3.8 L/min while the pressure is kept at 500 Torr. Instead of ClF₃, the etching gas may be, for example, Cl (chlorine) or SF₆ (sulfur hexafluoride). The diluting gas may be N₂ (nitrogen).

Where the etching gas is ClF₃, Cl or SF₆ and the diluting gas is Ar or N₂, the etching (immersing) of the substrate with NaOH or KOOH can be omitted and the etch time and concentration for the gas etching may be changed to such an extent that the damage caused by slicing can be sufficiently removed.

By conducting the etching as described above, porous regions each having a plurality of microscopic depressions 202 are formed on surfaces of the substrate 201 as shown in FIG. 9. Each depression has the form of a long pore. Such depressions in long pore form greatly reduce the light reflectivity. However, when a solar cell is formed to have such depressions, recombination of carriers in the surface of the cell occurs more often, affecting the properties of the solar cell.

Hence, wet etching is carried out on the substrate 201 using an acid etching solution to alter the depressions 202 (porous regions) to shallow depressions 203 as shown in FIG. 10, so that the surfaces of the substrate 201 are made smoother. The wet etching is performed by immersing the substrate 201 for two minutes into an acid etching solution in which 4,000 cc of a 60% nitric acid aqueous solution, 200 cc of a 49% hydrofluoric acid aqueous solution and 1,800 cc of pure water are mixed in volume ratios of 20:1:9. The wet etching of the substrate 201 is controlled such that the configuration and size of the depressions become as shown in the SEM photographs of FIG. 3 to FIG. 5 (preferably the configuration and size of the depressions in FIG. 3), that is, the wet etching is controlled such that the maximum depth/maximum diameter ratio of each of the depressions 203 becomes 0.5 to 2 (preferably 1).

Where the substrate 201 is etched with an acid etching solution in which, for example, 60% HNO₃ and 49% HF are mixed in a volume ratio of 10:1, the etch rate is about 5 μm/min, which is too fast for forming depressions each having a depth of about 1 μm to 2 μm. For this reason, when the etching solution has such a volume ratio, depressions of desirable size and configuration can not be formed with fine control. In the embodiment of the present invention, the aforementioned acid etching solution whose etch rate is at least 2 μm/min or lower is used, because in production facilities, it is easier to control the etch time in the unit of minutes.

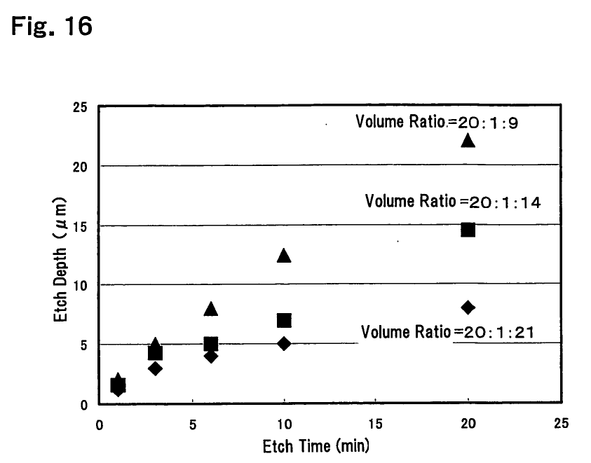

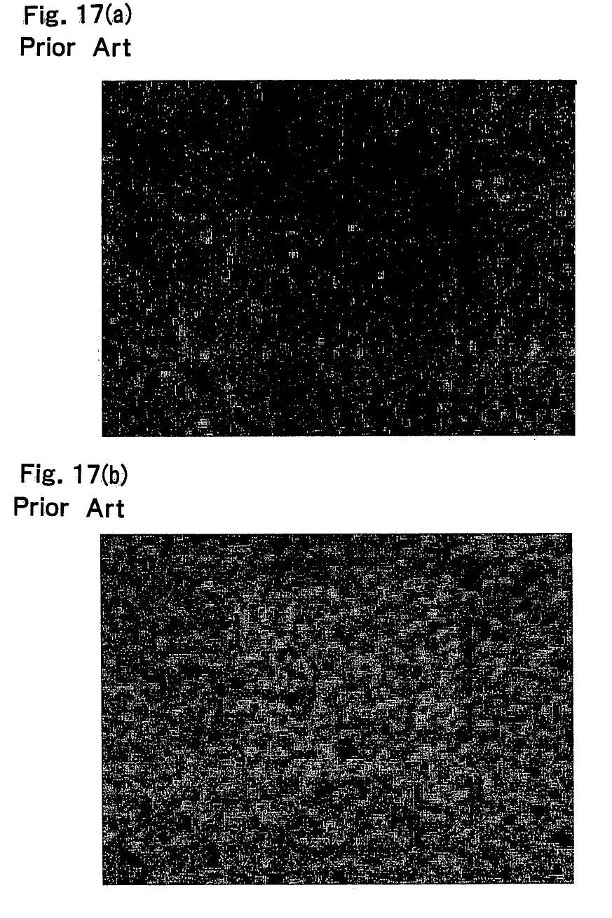

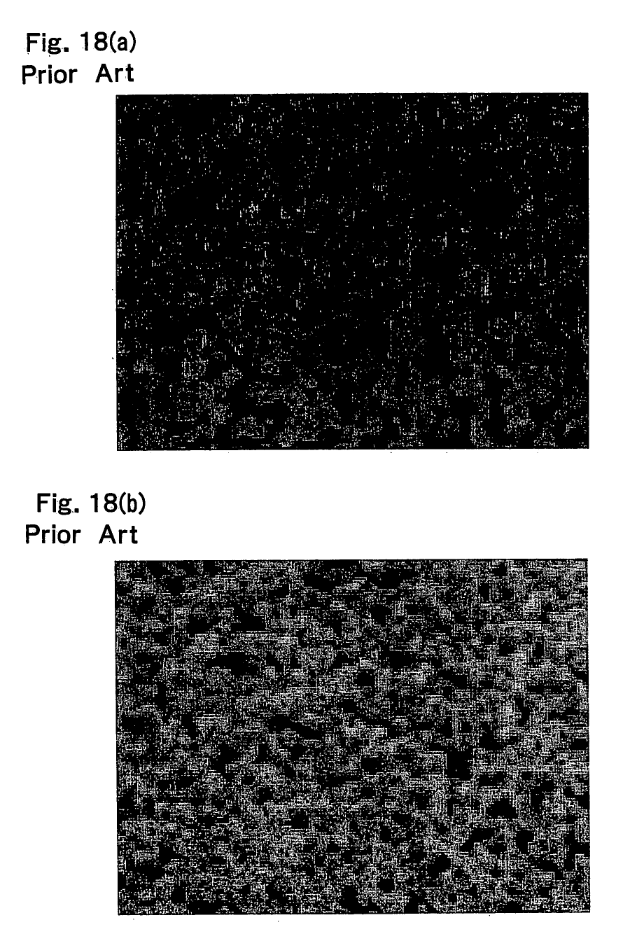

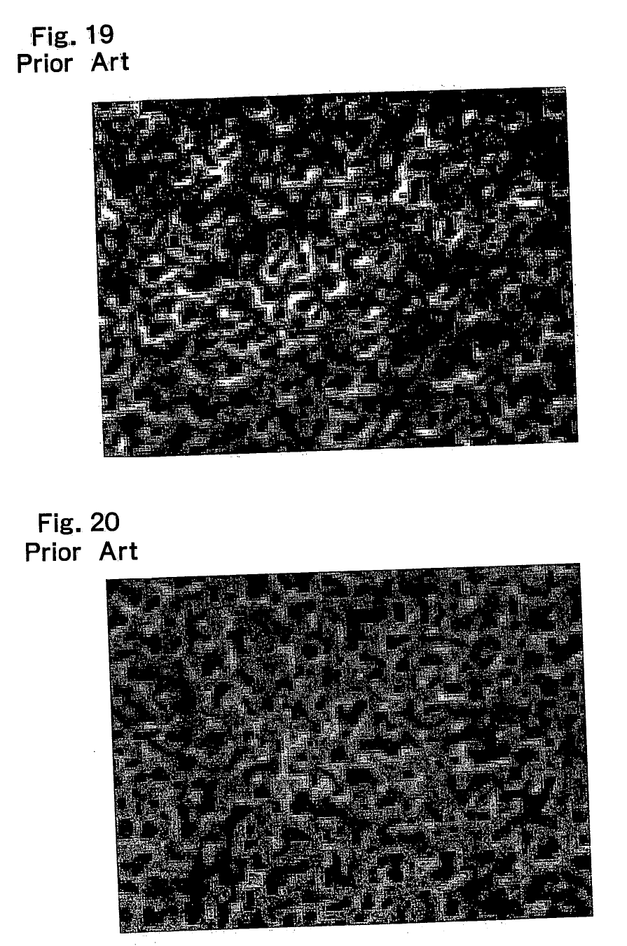

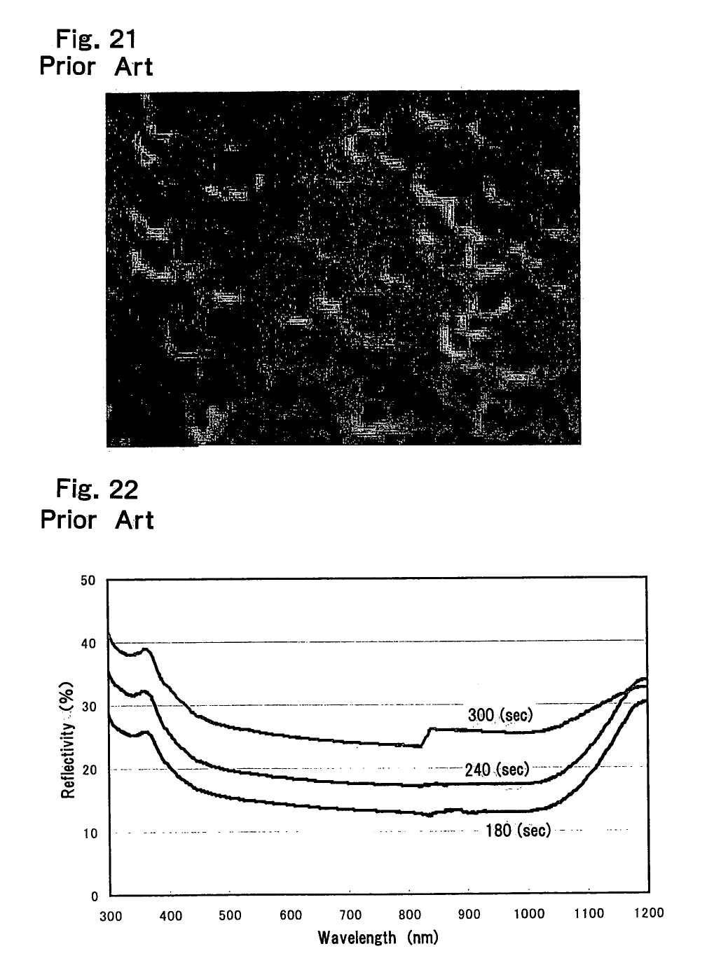

FIG. 16 is a diagram showing the etch depth dependence on the etch time in the wet etching of the present invention, when acid etching solutions in which a 60% nitric acid aqueous solution, a 49% hydrofluoric acid aqueous solution and pure water are mixed in different volume ratios (20:1:9, 20:1:14, 20:1:21). As is apparent from FIG. 16, for etching the substrate at least about 2 μm in a minute, the acid etching solution preferably contains a 60% nitric acid aqueous solution, a 49% hydrofluoric acid aqueous solution and pure water in the ratios of about 20:1:9, and more preferably, the acid etching solution contains a higher volume ratio of water.

In the embodiment of the present invention, the polycrystalline silicon substrate is etched for 2 minutes with the acid etching solution containing the 60% nitric acid aqueous solution, the 49% hydrofluoric acid aqueous solution and pure water in the ratios of about 20:1:9 to form the plurality of depressions 203 in the surfaces of the substrate 201 (see FIG. 10). Each of the depressions 203 thus formed has a maximum diameter of about 1 μm and a maximum depth of about 1 μm (see FIG. 3). In the method of the present invention using such an acid etching solution as described above, the alkaline etching performed prior to the dry etching may be omitted by increasing the total usage amount of the acid etching solution.

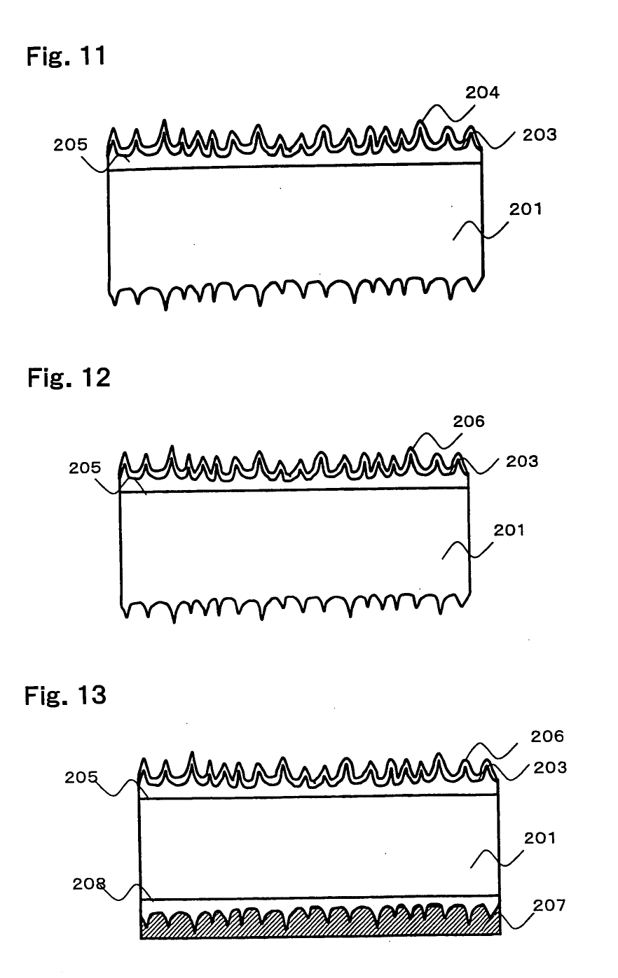

Then, as shown in FIG. 11, a diffusion-source layer 204 composed of PSG (P₂O₅ and SiO₂) is formed on the light-receiving surface of the substrate 201 by means of spin-coating, and a thermal treatment is performed at 900° C. for about 20 minutes to form an n+ diffusion region 205. The n+ diffusion region 205 is formed to have a junction depth of about 300 nm so that the incident light can be converted into the greatest amount of current.

As shown in FIG. 12, a silicon nitride film, for example, as an anti-reflection film 206 is deposited by means of plasma CVD. The thickness of the anti-reflection film 206 is set to 60 nm so that the light-receiving surface of the substrate 201 has the lowest reflectivity for incident light.

Subsequently, as shown in FIG. 13, an aluminum layer 207 is formed on the rear surface of the substrate 201 by means of printing. After the aluminum layer 207 is dried, a thermal treatment is performed at 600° C. to 800° C. to form a p+ layer 208 of aluminum by means of diffusion.

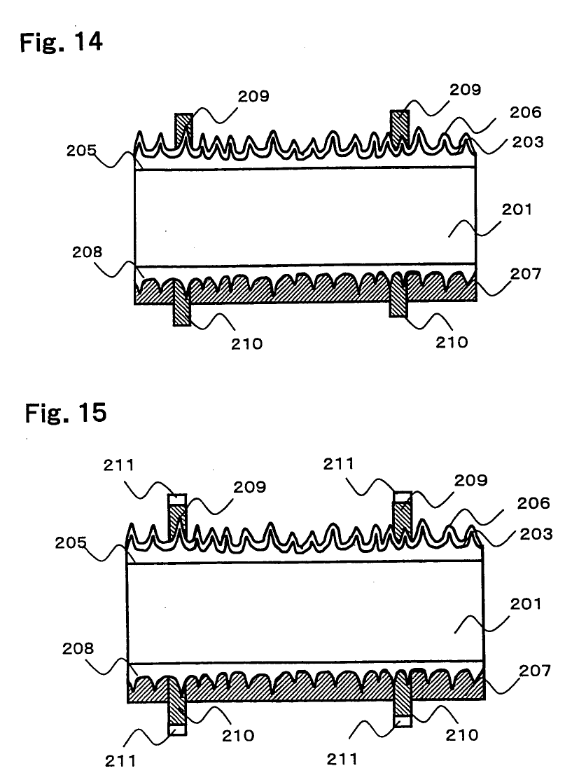

As shown in FIG. 14, a silver paste is then applied to the light-receiving surface and the rear surface of the substrate 201 by means of printing. After the paste is dried, a thermal treatment is performed at 600° C. to 800° C. to form front and rear silver electrodes 209, 210. In turn, as shown in FIG. 15, the surfaces of the electrodes 209, 210 are covered with solder 211 by means of printing to complete a solar cell.

The solar cell thus formed has an excellent textured surface (irregularities having excellent configuration and size) as shown in the SEM photograph of FIG. 3 and excellent solar cell properties.

In the solar cell production method of the present invention, the etching solution is not limited to the above-mentioned aqueous solution of nitric acid and hydrofluoric acid, and may be any as long as its etch rate is 2 μm or lower and the depressions formed using the solution has any of the configurations and sizes defined in Embodiments 1 to 3 (the configuration and size defined in Embodiment 1 is particularly preferable). For example, an etching solution in which acetic acid (CH₃COOH) and a mixture of nitric acid and hydrofluoric acid are mixed in an optimal ratio may be used.

The n+ diffusion region may be formed by diffusing POCl₃ or by ion-implantation.

In the method embodiment of the present invention, the polycrystalline silicon substrate is used. However, a single-crystal silicon substrate having crystal orientation (111) on which an excellent textured surface (irregularities having excellent configuration and size) can not be formed by alkaline etching may be used, and the same effects as those displayed by the polycrystalline silicon substrate can be achieved.

In the method embodiment of the present invention, the irregularities are formed on the rear surface of the silicon substrate as well as the light-receiving surface thereof, but an etch-resistant film may be formed on the rear surface of the substrate and the irregularities may only be formed on the light-receiving surface of the substrate.

1. A solar cell comprising at least:
a semiconductor substrate having a pn junction and a plurality of microscopic depressions formed in a light-receiving surface thereof;
a front electrode formed on the light-receiving surface of the substrate; and
a rear electrode formed on a rear surface of the substrate,
wherein the plurality of depressions each have a ratio of the maximum depth to the maximum diameter of 0.5 to 2.

2. A solar cell as recited in claim 1, wherein the plurality of depressions each have a ratio of the maximum depth to the maximum diameter of 1.

3. A solar cell as recited in claim 1, wherein the plurality of depressions each have a maximum diameter of 2 μm or smaller.

4. A solar cell as recited in claim 1, further comprising an anti-reflection film on the light-receiving surface having the microscopic depressions of the semiconductor substrate, the anti-reflection film having a refractive index of 1.9 to 2.1 and a thickness of 500 nm to 800 nm.

5. A solar cell as recited in claim 1, wherein the semiconductor substrate is a polycrystalline silicon substrate or a single-crystal silicon substrate having crystal orientation (111).

6. A method for producing a solar cell, comprising the steps of:
(a) forming a plurality of microscopic depressions in at least a light-receiving surface of a first-conductivity type semiconductor substrate;
(b) diffusing second-conductivity type impurities into the light-receiving surface having the microscopic depressions of the semiconductor substrate to form a pn junction in the substrate; and
(c) forming a front electrode and a rear electrode on the light-receiving surface and a rear surface of the semiconductor substrate, respectively,
wherein in the step (a), each of the plurality of microscopic depressions is formed to have a ratio of the maximum depth to the maximum diameter of 0.5 to 2.

7. A method for producing a solar cell as recited in claim 6, wherein the step (a) comprises:
(a1) forming the plurality of microscopic depressions in the light-receiving surface of the semiconductor substrate by means of dry etching; and
(a2) smoothing the light-receiving surface having the microscopic depressions by means of wet etching at an etch rate of 2 μm/min or lower using an etching solution containing a mixture of at least nitric acid, hydrofluoric acid and water.

8. A method for producing a solar cell as recited in claim 7, wherein the etching solution contains 140 parts by volume of water and 100 parts by volume of mixed acid of nitric acid and hydrofluoric acid.

9. A method for producing a solar cell as recited in claim 7, wherein the etching solution contains a 60% nitric acid aqueous solution, a 49% hydrofluoric acid aqueous solution and water in the ratios of 20:1:9 to 20:1:21.

10. A method for producing a solar cell as recited in claim 6, wherein the semiconductor substrate is a polycrystalline silicon substrate or a single-crystal silicon substrate having crystal orientation (111).
